(19) United States
(12) Patent Application Publication
(10) Pub. No.: US 2024/0304462 A1
(43) Pub. Date: Sep. 12, 2024

(54) METHOD FOR MANUFACTURING WIRING BOARD AND LAYERED PLATE

(71) Applicant: Resonac Corporation, Minato-ku, Tokyo (JP)

(72) Inventors: Masaya TOBA, Minato-ku, Tokyo (JP); Masaki YAMAGUCHI, Minato-ku, Tokyo (JP)

(21) Appl. No.: 18/569,217

(22) PCT Filed: Jun. 15, 2022
(86) PCT No.: PCT/JP2022/024007

§ 371 Date: Dec. 12, 2023

(30) Foreign Application Priority Data
Jun. 17, 2021 (WO) PCT/JP2021/023092

(51) Int. Cl. H01L 21/48; C23C 18/16; C23C 18/38; C23C 28/02; C25D 3/38; C25D 5/02; C25D 7/12; H01L 23/12; H05K 1/03; H05K 3/18

(52) U.S. Cl. CPC H01L 21/4857; C23C 18/1641; C23C 18/1653; C23C 18/38; C23C 28/023; C25D 3/38; C25D 5/022; C25D 7/123; H01L 23/12; H05K 1/0366; H05K 3/188; H05K 2203/107

(57) ABSTRACT

A method for manufacturing a wiring board includes steps of: (I) forming an insulation material layer on a surface of a support substrate; (II) forming a first conductive layer on a surface of the insulation material layer by electroless copper plating; (III) forming a first opening passing through the first conductive layer and the insulation material layer; (IV) forming a second conductive layer on a surface of the first conductive layer and on a bottom surface and a side surface of the first opening by electroless copper plating; (V) forming a resist pattern having a second opening communicating with the first opening on a surface of the second conductive layer; and (VI) filling the first opening and the second opening with a conductive material including copper by electrolytic copper plating.

### TECHNICAL FIELD

The present disclosure relates to a method for manufacturing a wiring board and a layered plate.

### BACKGROUND ART

A mounting type in which semiconductor elements (hereinafter, referred to as “chips” in some cases) having different performances are mixed and mounted in one package has been suggested for high density and high performance of a semiconductor package. From the viewpoint of the cost, the importance of a high-density interconnect technology between chips has been increased (refer to Patent Literature 1).

In smartphones and tablet terminals, a connection method called package-on-package has been widely employed. Package-on-package is a method of connecting a different package on a package with flip chip mounting (refer to Non-Patent Literatures 1 and 2). As a mounting type with further higher density, a packaging technology (organic interposer) using an organic substrate including a high-density wiring, a fan-out type packaging technology (FO-WLP) including a through mold via (TMV), a packaging technology using silicon or a glass interposer, a packaging technology using a through-silicon electrode (TSV), a packaging technology using a chip embedded in a substrate for inter-chip transmission, and the like have been suggested. Particularly, in the organic interposer and the FO-WLP, in a case where chips are mounted in parallel, a fine wiring layer is required for high-density conduction (refer to Patent Literature 2).

### CITATION LIST

### Patent Literature

Patent Literature 1: Japanese Unexamined Patent Publication No. 2003-318519
Patent Literature 2: Specification of U.S. Patent Application Publication No. 2011/0221071

### Non Patent Literature

Non Patent Literature 1: Application of Through Mold Via (TMV) as PoP Base Package, Electronic Components and Technology Conference (ECTC), 2008
Non Patent Literature 2: Advanced Low Profile POP Solution with Embedded Wafer Level POP (eWLB-POP) Technology, ECTC, 2012

### SUMMARY OF INVENTION

### Technical Problem

By the way, the present inventors manufactured a wiring board having a via by using a layered plate including a prepreg, and ultra-thin copper foil (thickness: approximately 1.5 to 5 μm) provided on a surface of the prepreg, and they found that the following problem exists in accordance with miniaturization of the via in recent years. That is, when forming an opening that passes through the copper foil and the prepreg with a carbon dioxide laser that is widely used in this field, a phenomenon in which the copper foil is peeled from the prepreg at the periphery of the opening was recognized. Even though peeling of conductive copper foil at the periphery of the opening for a via was at a level that can be ignored in the related art, since the opening for a via is also required to be miniaturized (for example, an opening diameter of approximately 10 to 100 μm), it is assumed that the peeling may have an influence on reliability of a via.

The present disclosure has been made in consideration of the problem, and the present disclosure provides a method for manufacturing a wiring board in which peeling of a conductive layer at the periphery of an opening is capable of being sufficiently suppressed even when forming the opening for forming a via with a carbon dioxide laser. The present disclosure provides a layered plate which is used in manufacturing of a wiring board, and in which peeling of a conductive layer at the periphery of an opening is capable of being sufficiently suppressed even when forming the opening for forming a via with a carbon dioxide laser, and the layered plate is also useful for manufacturing the wiring board with excellent reliability at a sufficiently high yield ratio.

### Solution to Problem

A method for manufacturing a wiring board according to the present disclosure includes steps of: (I) forming an insulation material layer on a surface of a support substrate; (II) forming a first conductive layer on a surface of the insulation material layer by electroless copper plating; (III) forming a first opening passing through the first conductive layer and the insulation material layer; (IV) forming a second conductive layer on a surface of the first conductive layer and on a bottom surface and a side surface of the first opening by electroless copper plating; (V) forming a resist pattern having a second opening communicating with the first opening on a surface of the second conductive layer; and (VI) filling the first opening and the second opening with a conductive material including copper by electrolytic copper plating.

The present inventors have found that the above-described problem can be solved by forming the insulation material layer on the surface of the support substrate, and forming the first conductive layer on the surface of the insulation material layer by electroless copper plating. That is, even when forming the first opening passing through the first conductive layer and the insulation material layer by using carbon dioxide laser after forming the first conductive layer, it is possible to sufficiently suppress the first conductive layer from being peeled from the insulation material layer at the periphery of the opening. It is estimated that the main reason for this effect is in that the first conductive layer formed by the electroless copper plating is thinner than copper foil. That is, the thickness of the first conductive layer formed in the step (II) is, for example, 20 to 590 nm. Since the first conductive layer is sufficiently thin, heat generated at the time of processing the opening with the carbon dioxide laser in the step (III) is likely to be dissipated, and it is possible to form the opening in the first conductive layer within a relatively short time. Therefore, it is estimated that peeling of the first conductive layer from the insulation material layer is less likely to occur at the periphery of the opening. That is, according to the present disclosure, it is possible to stably form vias (first and second openings) having a predetermined shape, and it is possible to manufacture a wiring board at a satisfactory yield ratio. In contrast, the thickness of ultra-thin copper foil that is used in a field of a wiring board in the related art is, for example, 1.5 to 5 μm. In a case of forming an opening with respect to a layered plate including copper foil having the thickness on an outermost surface with a carbon dioxide laser, dissipation of heat generated at the time of processing tends to be inhibited by the copper foil. As a result, it is estimated that heat is accumulated in an insulation material layer in the vicinity of the opening, and an insulation material is modified due to heat, and peeling of the copper foil tends to occur. Note that, since the carbon dioxide laser emits light in an infrared region, a temperature of a region irradiated with the carbon dioxide laser and the vicinity of the region is likely to rise. If peeling does not occur in the vicinity of the opening with the carbon dioxide laser, it can be said that peeling does not occur even when using other lasers (for example, a YAG laser, a UV-YAG laser, a green laser, a deep ultraviolet laser, and an excimer laser).

In the resist pattern in the step (V) may further have a plurality of grooves which extend to the surface of the second conductive layer and are provided in parallel. In this case, in the step (VI), the plurality of grooves are also filled with a conductive material by electrolytic copper plating to form a wiring. A width of each of the grooves is, for example, 1 to 100 μm. An interval between two adjacent grooves is, for example, 1 to 100 μm. Note that, “a width of a groove” and “an interval between two adjacent grooves” can also be respectively referred to as “a width of a wiring” and “an interval between two adjacent wirings”.

After the step (VI), steps until finally obtaining a wiring board are not particularly limited, but the wiring board is manufactured, for example, through the steps of: (VII) peeling the resist pattern; and (VIII) removing the second conductive layer exposed due to peeling of the resist pattern, and the first conductive layer that is in contact with the exposed second conductive layer.

The wiring layer that is formed on the support substrate may be a single layer or a multilayer. A wiring board including a multilayered wiring layer on the support substrate is manufactured, for example, through the steps of: (IX) further forming an insulation material layer to cover the wiring provided on the insulation material layer after the step (VIII); and (X) performing a series of steps from the step (II) to the step (IX) after the step (IX).

A layered plate according to the present disclosure includes: a support substrate; an insulation material layer provided on a surface of the support substrate; and a conductive layer provided on a surface of the insulation material layer in a thickness of 20 to 590 nm. The layered plate is used in manufacturing of a wiring board, and peeling of the conductive layer at the periphery of an opening for forming a via is capable of being sufficiently suppressed. The layered plate is also useful for manufacturing the wiring board with excellent reliability at a sufficiently high yield ratio. The conductive layer is formed by electroless copper plating. The conductive layer having the thickness can be formed by other methods (for example, sputtering or vapor deposition) instead of the electroless copper plating. According to the sputtering or the vapor deposition, it is possible to form a conductive layer that sufficiently and firmly adheres to the insulation material layer as in electroless copper plating.

The support substrate in the present disclosure includes, for example, a prepreg including cloth (for example, glass cloth), and a copper layer formed on a surface of the prepreg. The insulation material layer in the present disclosure is, for example, a prepreg including cloth (for example, glass cloth).

### Advantageous Effects of Invention

According to the present disclosure, there is provided a method for manufacturing a wiring board in which peeling of a conductive layer at the periphery of an opening is capable of being sufficiently suppressed even when forming the opening for forming a via with a carbon dioxide laser. According to the present disclosure, there is provided a layered plate which is used in manufacturing of a wiring board, in which peeling of a conductive layer at the periphery of an opening is capable of being sufficiently suppressed even when forming the opening for forming a via with a carbon dioxide laser, and the layered plate is also useful for manufacturing the wiring board with excellent reliability at a sufficiently high yield ratio.

### BRIEF DESCRIPTION OF DRAWINGS

(a) to (c) in FIG. 1 are cross-sectional views schematically illustrating a process of manufacturing a wiring board.

(a) to (c) in FIG. 2 are cross-sectional views schematically illustrating a process of manufacturing the wiring board.

(a) to (c) in FIG. 3 are cross-sectional views schematically illustrating a process of manufacturing the wiring board.

FIG. 4 is a cross-sectional view schematically illustrating the wiring board including a wiring layer formed on a surface of an insulation material layer.

FIG. 5 is a cross-sectional view schematically illustrating an embodiment of a layered body according to the present disclosure.

### DESCRIPTION OF EMBODIMENTS

Hereinafter, an embodiment of the present disclosure will be described with appropriate reference to the drawings. However, the present disclosure is not limited to the following embodiment. In the following embodiment, constituent elements (including steps and the like) of the embodiment are not essential unless otherwise stated. In the drawings, the size of the constituent elements is conceptual, and relative size relationships between the constituent elements are not limited to relative relationships shown in each of the drawings.

Numerical values and ranges thereof in this specification also do not limit the present disclosure. In this specification, a numerical value range expressed by using “to” represents a range including numerical values described before and after “to” as a minimum value and a maximum value. In a numerical range described stepwise in this specification, an upper limit value or a lower limit value described in one numerical value range may be replaced with an upper limit value or a lower limit value of another numerical value range described stepwise. In addition, in the numerical value range described in this specification, an upper limit value or a lower limit value of the numerical value range may be replaced with a value described in Examples.

### [Method for Manufacturing Wiring Board]

A method for manufacturing a wiring board according to this embodiment includes at least the following steps of:
(I) forming an insulation material layer 3 on a surface 7F of a support substrate 7;
(II) forming a first conductive layer 1 on a surface 3F of the insulation material layer 3 by electroless copper plating;
(III) forming a first opening H1 that extends from a surface 1F of the first conductive layer 1 to the surface 7F of the support substrate 7 passing through the insulation material layer 3 with a carbon dioxide laser;
(IV) forming a second conductive layer 2 on the surface 1F of the first conductive layer 1, and on a bottom surface H1a and a side surface H1b of the first opening H1 by electroless copper plating;
(V) forming a resist pattern 11 having a second opening H2 that communicates with the first opening H1 on a surface of the second conductive layer 2;
(VI) filling the first opening H1 and the second opening H2 with a conductive material 9a including copper by electrolytic copper plating;
(VII) peeling the resist pattern 11; and
(VIII) removing the second conductive layer 2 exposed due to peeling of the resist pattern 11, and the first conductive layer 1 that is in contact with the exposed second conductive layer 2.

One of characteristics of the above-described manufacturing method is in that the first conductive layer 1 formed in the step (II) is formed by electroless copper plating. The first conductive layer 1 formed by electroless copper plating is thinner than copper foil. The thickness of the first conductive layer 1 is, for example, 20 to 590 nm, or the thickness may be 20 to 200 nm or 210 to 590 nm. In contrast, the thickness of copper foil that is used in a field of a wiring board is, for example, 1.5 to 5 μm. Since the first conductive layer 1 is sufficiently thin, heat generated at the time of the carbon dioxide laser processing in the step (III) is likely to dissipate, and peeling at an interface between the insulation material layer 3 and the first conductive layer 1 is less likely to occur. According to this, it is possible to stably form vias (first and second openings) having a predetermined shape, and it is possible to manufacture a wiring board at a satisfactory yield ratio. Hereinafter, the respective steps will be described.

### <Step (I)>

This step is a step of forming the insulation material layer 3 on the surface 7F of the support substrate 7 ((a) in FIG. 1). The support substrate 7 has a copper layer 7a on a surface thereof. The copper layer 7a is formed on a surface of a substrate main body 7b. As the support substrate 7, for example, a copper clad laminate (CCL) can be used. The copper clad laminate includes a prepreg including cloth (for example, glass cloth), and a copper layer formed on a surface of the prepreg. Note that, the cloth included in the prepreg may be a woven fabric or a non-woven fabric. From the viewpoint of the strength of the prepreg, the cloth is preferably a woven fabric. On the other hand, from the viewpoint of flatness of the surface of the prepreg, cloth disposed at least in the vicinity of the surface of the prepreg is preferably a non-woven fabric.

The thickness of the support substrate 7 is, for example, 0.2 to 2.0 mm. When the thickness is 0.2 mm or more, there is a tendency that handling of the support substrate 7 is satisfactory. On the other hand, when the thickness is 2.0 mm or less, there is tendency that the material cost is suppressed to be low. A shape of the support substrate 7 may be a wafer shape or a panel shape. A diameter of a wafer-shaped substrate is, for example, 200 mm, and the diameter may be 300 mm or 450 mm. A length of one side of a rectangular panel is, for example, 300 to 700 mm.

Examples of a method for forming the insulation material layer 3 on the surface 7F of the support substrate 7 include atmospheric pressure pressing, vacuum pressing, vacuum lamination, roll lamination, and vacuum roll lamination. The vacuum pressing capable of laminating large area at once is preferable. A material constituting the insulation material layer 3 is, for example, a thermosetting insulation material. Examples of the thermosetting insulation material include a liquid thermosetting insulation material and a film-shaped thermosetting insulation material, and the film-shaped thermosetting insulation material is preferable from the viewpoint of film thickness flatness and the cost. From the viewpoint that a fine wiring can be formed, the thermosetting insulation material preferably contains a filler (filling material) having an average particle size of 500 nm or less (more preferably, 50 to 200 nm). The content of the filler is preferably 0 to 70 parts by mass with respect to 100 parts by mass of thermosetting insulation material excluding the filler, and more preferably 0 to 50 parts by mass.

In a case of using the film-shaped thermosetting insulation material, it is preferable to employ a thermosetting insulation film capable of being pressed at 40 to 250° C. In a thermosetting insulation film of which a pressing temperature is 40° C. or higher has appropriate tackiness at room temperature (approximately 25° C.), there is a tendency that handling is easy. In a thermosetting insulation film of which a pressing temperature is 250° C. or lower, there is a tendency that warpage after lamination is likely to be suppressed.

A coefficient of thermal expansion of the insulation material layer 3 after hardening is preferably 80×10⁻⁶/K or less from the viewpoint of suppression of warpage, and more preferably 70×10⁻⁶/K or less from the viewpoint of obtaining high reliability. In addition, the coefficient of thermal expansion is preferably 50×10⁻⁶/K or more from the viewpoint of obtaining stress relaxation properties and a high definition pattern.

The thickness of the insulation material layer 3 is preferably 50 μm or less, more preferably 40 μm or less, and still more preferably 30 μm or less. When thickness of the insulation material layer 3 is within the above-described ranges, for example, it is easy to satisfactorily form a fine first opening H1 (opening shape: a circular shape or an elliptical shape) in the step (III). The thickness of the insulation material layer 3 is preferably 1 μm or more from the viewpoint of insulation reliability.

As the insulation material layer 3, for example, a prepreg can be used. The prepreg includes cloth (for example, glass cloth), and a thermosetting resin composition impregnated in the cloth. The cloth included in the prepreg may be a woven fabric or a non-woven fabric. From the viewpoint of the strength of the prepreg, the cloth is preferably a woven fabric. On the other hand, from the viewpoint of flatness of the surface of the prepreg, cloth disposed at least in the vicinity of the surface of the prepreg is preferably a non-woven fabric.

### <Step (II)>

This step is a step of forming the first conductive layer 1 on the surface 3F of the insulation material layer 3 by electroless copper plating ((b) in FIG. 1). In order to cause palladium serving as a catalyst of electroless copper plating to be adsorbed to the surface of the insulation material layer 3, the surface of the insulation material layer 3 is washed with a pre-treatment liquid. The pre-treatment liquid may be a commercially available alkaline pre-treatment liquid containing sodium hydroxide or potassium hydroxide. A concentration of the sodium hydroxide or the potassium hydroxide is, for example, 1 to 30%. An immersion time in the pre-treatment liquid is, for example, 1 to 60 minutes. An immersion temperature is, for example, 25 to 80° C. After a pre-treatment, washing with city water, pure water, ultrapure water, or an organic solvent may be performed to remove a surplus pre-treatment liquid.

After removing the pre-treatment liquid, immersion and washing are performed in an acidic aqueous solution to remove alkali ions on the surface of the insulation material layer 3. The acidic aqueous solution may be an aqueous sulfuric acid solution, a concentration thereof is, for example, 1 to 20%, and an immersion time is, for example, 1 to 60 minutes. Washing may be performed with city water, pure water, ultrapure water, or an organic solvent to remove the acidic aqueous solution.

Next, palladium is caused to adhere to the surface of the insulation material layer 3. Palladium may be a commercially available palladium-tin colloidal solution, an aqueous solution containing palladium ions, a palladium ion suspension, or the like. Among these, the aqueous solution containing palladium ions is preferable from the viewpoint that palladium ions are effectively adsorbed to a region modified by the pre-treatment.

When performing immersion in the aqueous solution containing palladium ions, a temperature of the aqueous solution containing palladium ions is, for example, 25 to 80° C., and an immersion time is, for example, 1 to 60 minutes. After adsorption of palladium ions, washing may be performed with city water, pure water, ultrapure water, or an organic solvent to remove surplus palladium ions.

After adsorption of palladium ions, activation for causing palladium ions to operate as a catalyst is performed. A reagent that activates palladium ions may be a commercially available activation agent (activation treatment liquid). A temperature of the activation agent is, for example, 25 to 80° C., and an immersion time is, for example, 1 to 60 minutes. After activating palladium ions, washing may be performed with city water, pure water, ultrapure water, or an organic solvent to remove a surplus activation agent.

Next, electroless copper plating is performed on the surface of the insulation material layer 3 to form the first conductive layer 1. A copper content rate of the first conductive layer 1 is, for example, 90 to 99.9% by mass. The first conductive layer 1 plays a role of protecting the surface of the insulation material layer 3.

Examples of the electroless copper plating include electroless pure copper plating (purity: 99% by mass or more) and electroless copper-nickel-phosphorous plating (a nickel content: 1 to 10% by mass, a phosphorous content: 1 to 13% by mass), but non-magnetic electroless copper plating is preferable from the viewpoint of securing satisfactory signal integrity. An electroless copper plating liquid may be a commercially available plating liquid, and for example, an electroless copper plating liquid (product name: “True-Cup”, manufactured by C. Uyemura & Co., Ltd.) can be used. A temperature of the electroless copper plating liquid is, for example, 25 to 60° C. After the electroless copper plating, washing may be performed with city water, pure water, ultrapure water, or an organic solvent to remove a surplus plating liquid. Note that, in a case where film formation by electroless plating on the surface of the insulation material layer 3 is difficult, a surface treatment may be performed on the surface of the insulation material layer 3. Examples of a surface treatment method include oxygen plasma, argon plasma, nitrogen plasma, and ultraviolet rays-ozone modification.

The thickness of the first conductive layer 1 is, for example, 20 to 200 nm, or the thickness may be 40 to 200 nm or 60 to 200 nm. The thickness of the first conductive layer 1 may be, for example, 20 to 590 nm, 210 to 590 nm, 250 to 520 nm, 320 to 480 nm, or 350 to 440 nm. Since the first conductive layer 1 is sufficiently thin, it is possible to dissipate heat generated at the time of processing with the carbon dioxide laser in the step (III). According to an examination made by the present inventors, when the thickness of the first conductive layer 1 is 590 nm or less, peeling at an interface between the first conductive layer 1 and the insulation material layer 3 can be suppressed to a high degree. When the thickness of the first conductive layer 1 is 210 nm or more, an effect capable of easily controlling an electroless plating thickness in a substrate surface is obtained.

### <Step (III)>

This step is a step of forming the first opening H1 passing through the first conductive layer 1 and the insulation material layer 3 ((c) in FIG. 1). The first opening H1 extends from the surface 1F of the first conductive layer 1 to the surface 7F of the support substrate 7 passing through the insulation material layer 3. The first opening H1 includes the bottom surface H1a constituted by the surface of the support substrate 7 (surface of the copper layer 7a), and the side surface H1b. The bottom surface H1a is constituted by the surface of the support substrate 7 (surface of the copper layer 7a). The side surface H1b is constituted by the first conductive layer 1 and the insulation material layer 3. It is preferable that an opening shape of the first opening H1 is a circular shape or an elliptical shape, and an opening size in this case may be a size approximately equivalent to an area of a circle with a diameter of 10 to 100 μm (a diameter of 10 to 50 μm in a finer case).

A method of forming the first opening H1 is preferably carbon dioxide laser processing from the viewpoint of the cost. In a case where the insulation material layer 3 is formed from a thermosetting material, after forming the first opening H1, the insulation material layer 3 may be further hardened by heating. A heating temperature is, for example, 100 to 200° C., and a heating time is, for example, 30 minutes to 3 hours. After forming the first opening H1, in a case where a residue of the insulation material layer 3 remains at the periphery of a processing site, the residue may be removed by an oxygen plasma treatment, an argon plasma treatment, a nitrogen plasma treatment, and a treatment with a desmear liquid. Note that, the treatment for removing the residue may roughen a surface of a treatment target. This tends to deteriorate, for example, transmission properties of high-frequency signals. In this embodiment, since a layered body in a state in which the insulation material layer 3 is covered with the first conductive layer 1 is set as the treatment target, even when performing the treatment, the surface of the insulation material layer 3 can be suppressed from being roughened. That is, in a process of manufacturing a wiring board, the first conductive layer 1 can play a role of protecting the surface of the insulation material layer 3.

### <Step (IV)>

This step is a step of forming the second conductive layer 2 on the surface 1F of the first conductive layer 1, the bottom surface H1a and the side surface H1b of the first opening H1 by electroless copper plating ((a) in FIG. 2). An electroless plating method may be the same as in the step (II). The second conductive layer 2 serves as a seed layer (power feed layer) of electrolytic copper plating performed in the step (VI). The thickness of the second conductive layer 2 may be, for example, 20 to 200 nm, 40 to 200 nm, or 60 to 200 nm. When the thickness of the second conductive layer 2 is 20 nm or more, electric resistance at the time of electrolytic plating is lowered, and thus there is a tendency that an effect capable of suppressing a variation of a plating thickness of the entirety of a panel is exhibited. On the other hand, when the thickness is 200 nm or less, an effect that seed etching is easy tends to be exhibited. The second conductive layer 2 is preferably thinner than the first conductive layer 1 from the viewpoint of seed etching. A ratio (T2/T1) of the thickness T2 of the second conductive layer 2 to the thickness T1 of the first conductive layer 1 is, for example, 0.2 to 0.8, and the ratio may be 0.4 to 0.8 or 0.6 to 0.8. When the ratio is 0.2 or more, an effect that electrolytic plating properties of the opening become satisfactory tends to be exhibited. On the other hand, when the ratio is 0.8 or less, an effect that seed etching is easy tends to be exhibited.

### <Step (V)>

This step is a step of forming the resist pattern 11 having the second opening H2 communicating with the first opening H1 on the surface of the second conductive layer 2 ((b) in FIG. 2). The second opening H2 is formed at a position where the first opening H1 is formed. An opening shape of the second opening H2 is, for example, a circular shape or an elliptical shape, and an opening size may be a size approximately equivalent to an area of a circle with a diameter of 15 to 120 μm (a diameter of 15 to 60 μm in a finer case).

As illustrated in (b) in FIG. 2, the resist pattern 11 may have a plurality of grooves G for forming a fine wiring. The plurality of grooves G are provided in parallel to extend to a surface of the second conductive layer H2. The grooves G preferably have a trench structure. The plurality of grooves G are filled with a conductive material by electrolytic copper plating in the step (VI). The conductive material constitutes a wiring. A width of each of the grooves G is, for example, 1 to 100 μm. An interval between two adjacent grooves G is, for example, 1 to 100 μm.

The resist pattern 11 may be formed by using a commercially available resist. Examples of the commercially available resist include a negative-type film-shaped photosensitive resist (Photec RY-5107UT, manufactured by Showa Denko Materials Co., Ltd.). The resist pattern 11 can be formed through the following steps. First, a resist is formed as a film by using a roll laminator. Then, a photo tool on which a pattern is formed is brought into close contact with the resist, and exposure is performed by using an exposer. Then, spray development is performed with an aqueous sodium carbonate solution. Note that, a positive-type photosensitive resist may be used instead of the negative type.

### <Step (VI)>

This step is a step of filling the first opening H1 and the second opening H2 with the conductive material 9a including copper by electrolytic copper plating ((c) in FIG. 2). In the step, the plurality of grooves G are filled with a conductive material 9b by electrolytic copper plating. Specifically, electrolytic copper plating is performed by using the second conductive layer 2 formed in the step (IV) set as a seed layer so as to fill the first opening H1 and the second opening H2 with the conductive material 9a, and to fill the plurality of grooves G with the conductive material 9b. The thickness (the thickness of a wiring) of the conductive material 9b that fills the plurality of grooves G is, for example, 1 to 30 μm, and the thickness may be 3 to 30 μm or 5 to 30 μm.

### <Step (VII)>

This step is a step of peeling the resist pattern 11 ((a) in FIG. 3). Peeling of the resist may be performed by using a commercially available peeling liquid.

### <Step (VIII)>

This step is a step of removing the second conductive layer 2 that is exposed due to peeling of the resist pattern 11, and the first conductive layer 1 adjacent to the exposed second conductive layer 2. ((b) in FIG. 3). More specifically, the second conductive layer 2 in a region not covered with the conductive materials 9a and 9b (region exposed due to peeling of the resist pattern 11) in the second conductive layer 2, and the first conductive layer 1 are removed, and the catalyst for electroless plating which remains below the region are removed. The removal may be performed by using a commercially available removal solution (etching solution), and specific examples thereof include an acidic etching solution (BB-20, PJ-10, SAC-700W3C, manufactured by JCU CORPORATION).

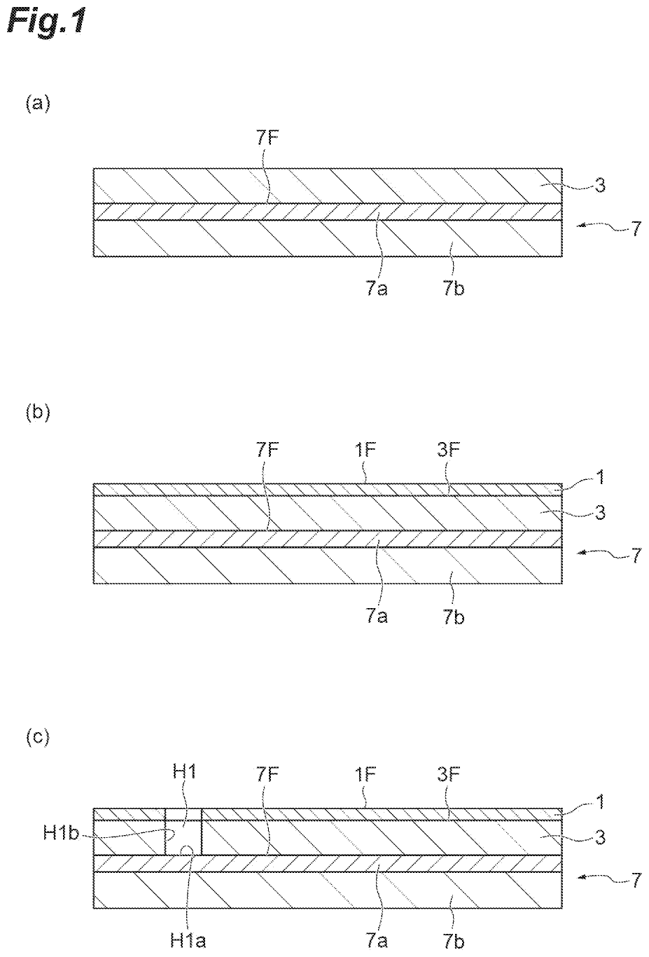

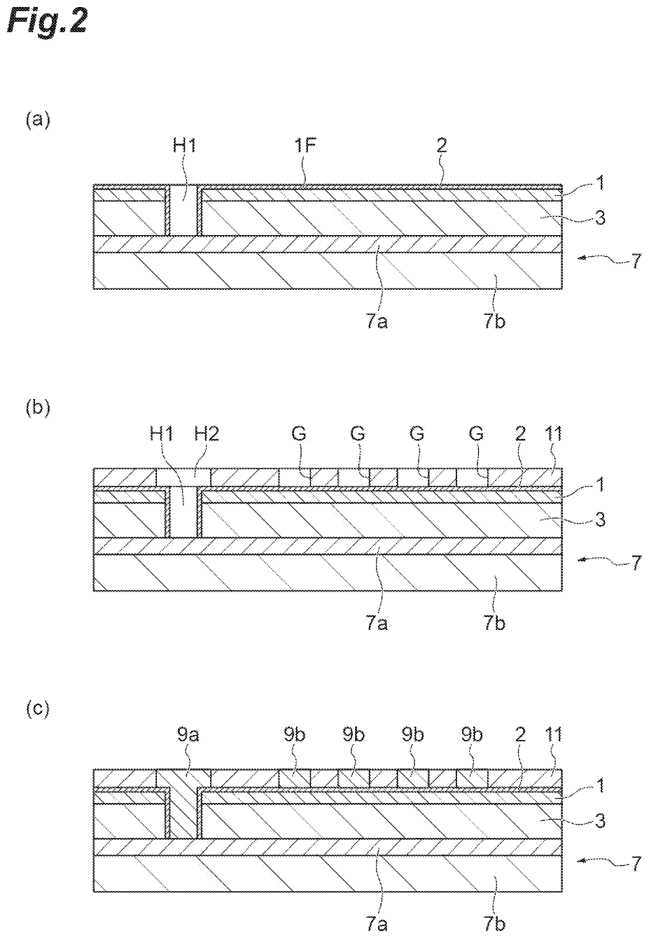

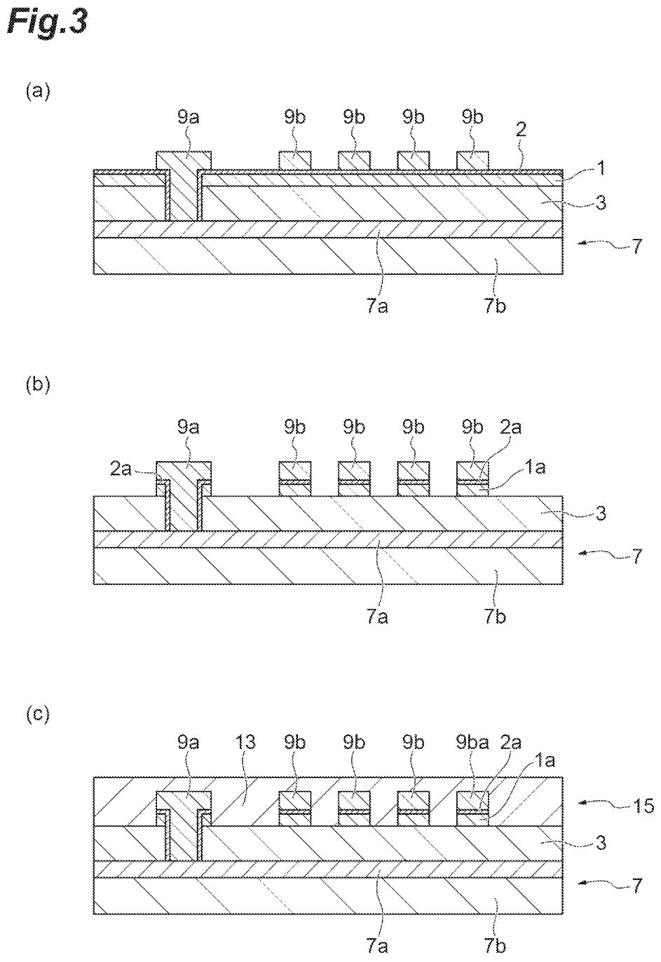

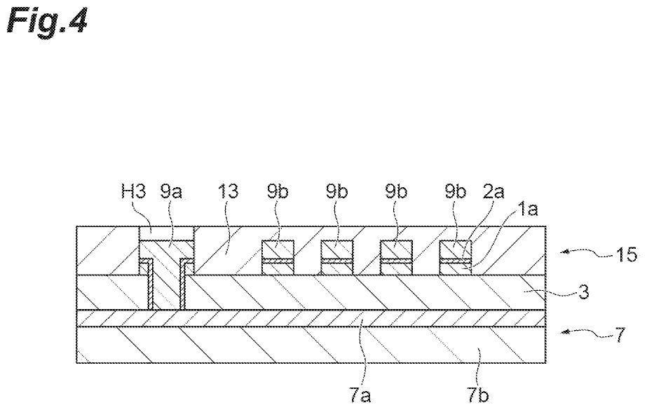

Since unnecessary portions of the first conductive layer 1 and the second conductive layer 2 are removed, a fine wiring is constituted by the conductive material 9b, a remaining portion 2a of the second conductive layer 2, and a remaining portion 1a of the first conductive layer 1. Then, an insulation material layer 13 is formed to cover a surface of the insulation material layer 3, the fine wiring, and the conductive material 9a (step (IX)). According to this, a wiring layer 15 including the insulation material layer 13 and the fine wiring embedded in the insulation material layer 13 is formed (refer to (c) in FIG. 3). Then, an opening H3 that extends to the conductive material 9a is formed in the insulation material layer 13 (refer to FIG. 4). A via hole is formed by the openings H1, H2, and H3. A wiring board is completed by filling the via hole with a conductive material, and performing finish processing of a surface, and the like.

Hereinbefore, the method for manufacturing a wiring board has been described, but the invention is not necessarily limited to the above-described embodiment, and may be appropriately modified within a range not departing from the gist of the invention.

For example, in the above-described embodiment, a method for manufacturing a wiring board including a single-layer wiring layer has been exemplified, but a wiring board including a multilayered wiring layer may be manufactured. A wiring board including the multilayered wiring layer on a support substrate can be manufactured by carrying out a series of steps from the step (II) to the step (IX) on a layered body in a state after the step (IX) illustrated in FIG. 4.

In the above-described embodiment, an aspect in which the step (II) of forming the first conductive layer 1 on the surface of the insulation material layer 3 by electroless copper plating is carried out has been exemplified, but a layered body having a similar configuration as in the layered body illustrated in (b) in FIG. 1 may be prepared in advance, and a wiring board may be manufactured by using the prepared layered body.

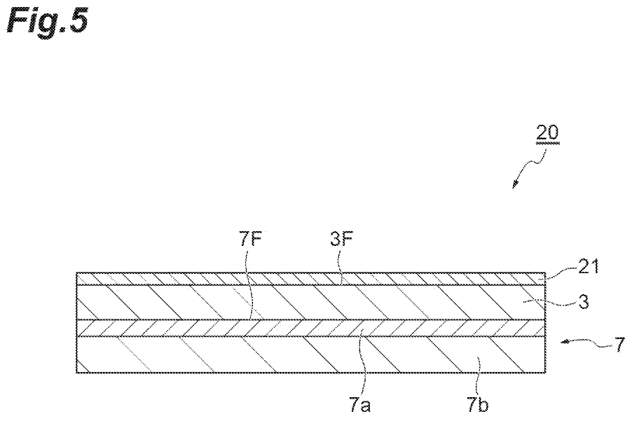

A layered plate 20 illustrated in FIG. 5 includes the support substrate 7, the insulation material layer 3 provided on the surface 7F of the support substrate 7, and a conductive layer 21 that is provided on the surface 3F of the insulation material layer 3 in a thickness of 20 to 590 nm. The conductive layer 21 may be formed by electroless copper plating, or may be formed by another method (for example, sputtering or vapor deposition). When using sputtering or vapor deposition, it is possible to form a conductive layer that sufficiently and firmly adheres to the insulation material layer as in electroless copper plating. The thickness of the conductive layer 21 is, for example, 20 to 590 nm, and the thickness may be 20 to 200 nm, 40 to 200 nm, or 60 to 200 nm. The thickness of the conductive layer 21 may be, for example, 210 to 590 nm, 250 to 520 nm, 320 to 480 nm, or 350 to 440 nm.

The present disclosure relates to the following matters.
[1] A method for manufacturing a wiring board, including steps of:
(I) forming an insulation material layer on a surface of a support substrate;
(II) forming a first conductive layer on a surface of the insulation material layer by electroless copper plating;
(III) forming a first opening passing through the first conductive layer and the insulation material layer;
(IV) forming a second conductive layer on a surface of the first conductive layer and on a bottom surface and a side surface of the first opening by electroless copper plating;
(V) forming a resist pattern having a second opening communicating with the first opening on a surface of the second conductive layer; and
(VI) filling the first opening and the second opening with a conductive material including copper by electrolytic copper plating.
[2] The method for manufacturing a wiring board according to [1], wherein the thickness of the first conductive layer is 20 to 590 nm.
[3] The method for manufacturing a wiring board according to [1], wherein the thickness of the first conductive layer is 210 to 590 nm.
[4] The method for manufacturing a wiring board according to any one of [1] to [3], wherein in the step (III), the first opening is formed with a carbon dioxide laser.
[5] The method for manufacturing a wiring board according to any one of [1] to [4],
wherein the resist pattern in the step (V) further has a plurality of grooves which extend to the surface of the second conductive layer and are provided in parallel, and
in the step (VI), the plurality of grooves are also filled with a conductive material including copper by electrolytic copper plating to form a wiring.
[6] The method for manufacturing a wiring board according to [5], wherein a width of each of the grooves is 1 to 100 μm, and an interval between two adjacent grooves is 1 to 100 μm.
[7] The method for manufacturing a wiring board according to any one of [1] to [6], further including steps of:
(VII) peeling the resist pattern; and
(VIII) removing the second conductive layer exposed due to peeling of the resist pattern, and the first conductive layer that is in contact with the exposed second conductive layer.
[8] The method for manufacturing a wiring board according to [7],
wherein a multi-layered wiring layer is formed on the support substrate through steps of:
(IX) further forming an insulation material layer to cover the wiring provided on the insulation material layer after the step (VIII); and
(X) performing a series of steps from the step (II) to the step (IX) after the step (IX).
[9] A layered plate, including:
a support substrate;
an insulation material layer provided on a surface of the support substrate; and
a conductive layer provided on a surface of the insulation material layer in a thickness of 20 to 590 nm.
[10] The layered plate according to [9], wherein the thickness of the conductive layer is 210 to 590 nm.
[11] The layered plate according to [9] or [10], wherein the support substrate includes a prepreg including cloth, and a copper layer formed on a surface of the prepreg.
[12] The layered plate according to any one of [9] to [11], wherein the insulation material layer is a prepreg including cloth.

### EXAMPLES

The present disclosure will be described in more detail with reference to Examples and Comparative Examples, but the invention is not limited to the following examples.

### Example 1

### <Step (I)>

A support substrate including a glass cloth-containing substrate (size: 200 mm square, thickness: 1.5 mm) and a copper layer (thickness: 20 μm) provided on a surface of the substrate was prepared. In a state in which Prepreg 1 (E-705G, manufactured by Showa Denko Materials Co., Ltd.) was placed on a surface of the support substrate on a copper layer side, pressing was performed by using a press-type vacuum laminator (MVLP-500, manufactured by Meiki Co., Ltd.). Press conditions were set as follows.
Press hot plate temperature: 70° C.
Vacuum processing time: 20 seconds
Press time: 40 seconds
Press pressure: 0.5 MPa
Atmospheric pressure: 4 kPa or lower
Then, additional pressing was performed by using a pressing machine. Press conditions were set as follows.
Temperature was raised up to 220° C. during press time from 0 to 60 minutes
Temperature was maintained at 220° C. during press time from 60 to 190 minutes
Temperature was lowered up to 25° C. during press time from 190 to 220 minutes
Press pressure: 2.0 MPa
Atmospheric pressure: 4 kPa

### <Step (II)>

An electroless copper plating layer (first conductive layer) was formed on a surface of Prepreg 1 (insulation material layer) in a layered body obtained through the step (I) by electroless copper plating as follows. First, the layered body was immersed in a 110 mL/L aqueous solution of an alkaline cleaner (trade name: EC-B, manufactured by JCU CORPORATION) at 50° C. for 5 minutes, and then the layered body was immersed in pure water for 1 minute. Next, the layered body was immersed in a mixed liquid (a concentration of PB-200: 70 mL/L and a concentration of EC-B: 2 mL/L) of a conditioning liquid (trade name: PB-200, manufactured by JCU CORPORATION) and EC-B at 50° C. for 5 minutes, and the layered body was immersed in pure water for 1 minute. Next, the layered body was immersed in a mixed liquid (a concentration of PB-228: 100 g/L and a concentration of sulfuric acid: 50 mL/L) of a soft etchant (trade name: PB-228, manufactured by JCU CORPORATION) and 98% sulfuric acid at 30° C. for 2 minutes, and the layered body was immersed in pure water for 1 minute. Next, the layered body was immersed in 10% sulfuric acid as desmear at room temperature for 1 minute. Next, the layered body was immersed in a mixed liquid (a concentration of PC-BA: 5 g/L, a concentration of PB-333: 40 mL/L, and a concentration of EC-B: 9 mL/L) of Regent 1 for catalyzing (trade name: PC-BA, manufactured by JCU CORPORATION), Reagent 2 for catalyzing (trade name: PB-333, manufactured by JCU CORPORATION), and EC-B at 60° C. for 5 minutes, and the layered body was immersed in pure water for 1 minute. Next, the layered body was immersed in a mixed liquid (a concentration of PC-66H: 10 mL/L and a concentration of PC-BA: 5 g/L) of a reagent for accelerator (trade name: PC-66H, manufactured by JCU CORPORATION), and PC-BA at 30° C. for 5 minutes, and the layered body was immersed in pure water for 1 minute.

Next, the layered body was immersed in a mixed liquid (a concentration of AISL-570B: 70 mL/L, a concentration of AISL-570C: 24 mL/L, a concentration of AISL-570MU: 50 mL/L, and a concentration of PC-BA: 13 g/L) of electroless copper-nickel-phosphorous plating liquids (trade names: AISL-570B, AISL-570C, and AISL-570MU, manufactured by JCU CORPORATION), and PC-BA at 60° C. for 7 minutes, and the layered body was immersed in pure water for 1 minute. Then, the layered body was dried on a hot plate kept at 85° C. for 5 minutes. Next, thermal annealing was performed in an oven kept at 180° C. for 1 hour. According to this, the layered body including the support substrate, Prepreg 1, and the electroless copper plating layer (thickness: approximately 90 nm, a copper content: 94% by mass, and a nickel content: 6% by mass) in this order was obtained.

### <Step (III)>

Next, a plurality of openings (first openings) which pass through the electroless copper plating layer and Prepreg 1 and extend to a surface of the copper layer of the support substrate were formed by using a carbon dioxide laser processing machine (LUC-2K21, laser wavelength: 9.4 μm, manufactured by Via Mechanics, Ltd.). A pulse width of a laser was set to 4 μm. The plurality of openings were set to have opening diameters different from each other, and the opening diameters were set to four types including 10 μm, 50 μm, 80 μm, and 100 μm.

After forming the openings, a treatment (desmear treatment) for removing a residue was performed. As a pre-treatment liquid, a swelling liquid (trade name: Swelling Dip Securiganth, manufactured by Atotech Japan K.K.) was used. As a desmear liquid, a roughening liquid (trade name: Concentrate Compact CP, manufactured by Atotech Japan K.K.) was used. As a chemical solution that is used for neutralization after the desmear treatment, a neutralization liquid (trade name: Reduction Securiganth, manufactured by Atotech Japan K.K.) was used.

### <Step (IV)>

After the desmear treatment, an electroless copper plating layer (second conductive layer) was formed on a surface of the electroless copper plating layer, and a bottom surface and a side surface of the openings by electroless copper plating. Formation conditions of the electroless copper plating layer were set to the same as the conditions in the step (II).

### <Step (V)>

A resist for wiring formation (RY-5107UT, manufactured by Showa Denko Materials Co., Ltd.) was vacuum-laminated on the surface of the electroless copper plating layer formed in the step (IV) by using a vacuum laminator (V-160, manufactured by Nichigo-Morton Co., Ltd.). A lamination temperature was set to 110° C., a lamination time was set to 60 seconds, and a lamination pressure was set to 0.5 MPa.

After the vacuum lamination, the resist for wiring formation was left for one day, and the resist for wiring formation was exposed by using an i-ray stepper exposer (product name: S6CK-type exposer, lens: ASC3 (Ck), manufactured by CERMA PRECISION, INC.). An exposure amount was set to 140 mJ/cm², and a focus was set to −15 μm. After the exposure, the resist for wiring formation was left for one hour, a protective film of the resist for wiring formation was peeled, and the resist for wiring formation was developed by using a spray developer (AD-3000, manufactured by Mikasa Co., Ltd.). A developing solution was 1.0% aqueous sodium carbonate solution, and a development temperature was set to 30° C., and a spray pressure was set to 0.14 MPa.

### <Step (VI)>

The openings were filled with a conductive material by electrolytic copper plating. First, the layered body was immersed in 100 mL/L aqueous solution of a cleaner (trade name: ICP clean S-135, manufactured by OKUNO Chemical Industries Co., Ltd.) at 50° C. for 1 minute, and was immersed in pure water at 50° C. for 1 minute. Then, the layered body was immersed in pure water at 25° C. for 1 minute, and was immersed in a 10% sulfuric acid aqueous solution at 25° C. for 1 minute. Next, electrolytic plating was performed under conditions of a temperature of 25° C., a current density of 1.5 A/dm², and for 10 minutes in an aqueous solution obtained by adding 0.25 mL of hydrochloric acid, 10 mL of TOP LUCINA GT-3 (trade name, manufactured by OKUNO Chemical Industries Co., Ltd.), and 1 mL of TOP LUCINA GT-2 (trade name, manufactured by OKUNO Chemical Industries Co., Ltd.) to 7.3 L of aqueous solution of 120 g/L of copper sulfate pentahydrate and 220 g/L of 96% sulfuric acid. Then, the layered body was immersed in pure water at 25° C. for 5 minutes, and was dried on a hot plate kept at 80° C. for 5 minutes.

### <Step (VII)>

The resist pattern was peeled by using a spray developer (AD-3000, manufactured Mikasa Co., Ltd.). As a peeling liquid, 2.38% TMAH aqueous solution was used. A peeling temperature was set to 40° C., and a spray pressure was set to 0.2 MPa.

### <Step (VIII)>

The electroless copper plating layer and a palladium catalyst were removed. In order to remove the electroless copper plating layer, the layered body was immersed in an aqueous solution of an etching solution (SAC-700W3C, manufactured by JCU CORPORATION), 98% sulfuric acid, 35% hydrogen peroxide solution, and copper sulfate pentahydrate (a concentration of SAC-700W3C: 5% by volume, a concentration of sulfuric acid: 4% by volume, a concentration of hydrogen peroxide: 5% by volume, and a concentration of copper sulfate pentahydrate: 30 g/L) at 35° C. for 1 minute. Next, in order to remove the palladium catalyst, the layered body was immersed in FL aqueous solution (FL-A 500 mL/L and FL-B 40 mL/L, manufactured by JCU CORPORATION) at 50° C. for 1 minute. Next, the layered body was immersed in pure water at 25° C. for 5 minutes, and was dried on a hot plate kept at 80° C. for 5 minutes.

### Examples 2 to 4

The respective steps were carried out in a similar manner as in Example 1 except that the following prepregs were respectively used instead of Prepreg 1.
Prepreg 2 (E-770G, manufactured by Showa Denko Materials Co., Ltd.)
Prepreg 3 (HS-200, manufactured by Showa Denko Materials Co., Ltd.)
Prepreg 4 (LW-910G, manufactured by Showa Denko Materials Co., Ltd.)

### Example 5

The respective steps were carried out in a similar manner as in Example 1 except that the thickness of the electroless copper plating layer (first conductive layer) formed in the step (II) was set to approximately 180 nm instead of approximately 90 nm.

### Example 6

The respective steps were carried out in a similar manner as in Example 1 except that the thickness of the electroless copper plating layer (first conductive layer) formed in the step (II) was set to approximately 500 nm instead of approximately 90 nm.

### Example 7

The respective steps were carried out in a similar manner as in Example 1 except that the thickness of the electroless copper plating layer (first conductive layer) formed in the step (II) was set to approximately 600 nm instead of approximately 90 nm.

### Comparative Example 1

### <Preparation of Copper Foil-attached Support Substrate>

Prepreg 1 and copper foil (GTS-MP, thickness: 12 μm, manufactured by Furukawa Electric Co., Ltd.) was placed in this order on a surface of a glass cloth-containing substrate (size: 200 mm square, thickness: 1.5 mm). The resultant stacked body was pressed by using a press-type vacuum laminator (MVLP-500, manufactured by Meiki Co., Ltd.). Press conditions were set as follows.
Press hot plate temperature: 70° C.
Vacuum processing time: 20 seconds
Lamination press time: 40 seconds
Press pressure: 0.5 MPa
Atmospheric pressure: 4 kPa or lower
Then, additional pressing was performed by using a pressing machine. Press conditions were set as follows.
Temperature was raised up to 220° C. during press time from 0 to 60 minutes
Temperature was maintained at 220° C. during press time from 60 to 190 minutes
Temperature was lowered up to 25° C. during press time from 190 to 220 minutes
Press pressure: 2.0 MPa
Atmospheric pressure: 4 kPa

### <Half Etching and Blacking Processing>

A surface of the copper foil was half-etched to reduce the thickness of the copper foil from 12 μm to 4 μm. Then, the thickness of the copper foil was reduced to 3 μm by blacking processing, and the surface of the copper foil was made to be black. The subsequent respective steps (the step (III) to the step (VIII)) were carried out in a similar manner as in Example 1.

### Comparative Examples 2 to 4

The respective steps were carried out in a similar manner as in Comparative Example 1 except that the prepregs were respectively used instead of Prepreg 1.

### [Evaluations]

### <Regarding Occurrences of Peeling in Vicinity of Openings>

With respect to the vicinity of the openings after the step (VIII), a cross-sectional analysis was performed by using an FIB device (MI-4050, manufactured by Hitachi High-Tech Corporation). With respect to Examples 1 to 7, an investigation was made on occurrences of peeling at an interface between the electroless copper plating layer (first conductive layer) and the prepreg. With respect to Comparative Examples 1 to 4, an investigation was made on occurrences of peeling at an interface between the copper foil and the prepreg. In addition, with respect to Examples 1 to 7, an investigation was made on occurrences of peeling at an interface between an electroless plating and the prepreg after a reliability test. The reliability test was performed under the following conditions. First, the layered body according to each of the examples was accommodated in a thermo-hydrostat (trade name: PR-2KP, manufactured by ESPEC CORP.) kept at 85° C. and 60% relative humidity for 168 hours, and a moisture absorption test was performed. Then, a reflow test was performed three times at a maximum temperature of 275° C. by using a nitrogen atmosphere reflow device (trade name: SNR-1065GT, manufactured by SENJU METAL INDUSTRY CO., LTD.). With respect to openings having opening diameters of 10 μm, 50 μm, 80 μm, and 100 μm, an opening without peeling was determined as “no”, and an opening with peeling was determined as “yes”. Results are shown in Tables 1 and 2.

TABLE 1

| | | Ex. 1 | Ex. 2 | Ex. 3 | Ex. 4 | Ex. 5 | Ex. 6 | Ex. 7 |
|---|---|---|---|---|---|---|---|---|
| Prepreg Nos. | | 1 | 2 | 3 | 4 | 1 | 1 | 1 |
| Thickness of electroless | | approx. | approx. | approx. | approx. | approx. | approx. | approx. |
| plating layer | | 90 nm | 90 nm | 90 nm | 90 nm | 180 nm | 500 nm | 600 nm |
| No peeling or | 10 μm | No | No | No | No | No | No | No |
| peeling (yes) | 50 μm | No | No | No | No | No | No | No |
| | 80 μm | No | No | No | No | No | No | No |
| | 100 μm | No | No | No | No | No | No | No |
| No peeling or | 10 μm | No | No | No | No | No | No | Yes |
| peeling (yes) | 50 μm | No | No | No | No | No | No | Yes |
| (after reliability | 80 μm | No | No | No | No | No | No | Yes |
| test) | 100 μm | No | No | No | No | No | No | Yes |

TABLE 2

| | | Comp. | Comp. | Comp. | Comp. |
|---|---|---|---|---|---|
| | | Ex. 1 | Ex. 2 | Ex. 3 | Ex. 4 |
| Prepreg Nos. | | 1 | 2 | 3 | 4 |
| Thickness of copper foil | | 3 μm | 3 μm | 3 μm | 3 μm |
| No peeling or | 10 μm | Yes | Yes | Yes | Yes |
| peeling (yes) | 50 μm | Yes | Yes | Yes | Yes |
| | 80 μm | Yes | Yes | Yes | Yes |
| | 100 μm | Yes | Yes | Yes | Yes |

### INDUSTRIAL APPLICABILITY

According to the present disclosure, there is provided a method for manufacturing a wiring board in which peeling of a conductive layer at the periphery of an opening is capable of being sufficiently suppressed even when forming the opening for forming a via with a carbon dioxide laser. According to the present disclosure, there is provided a layered plate which is used in manufacturing of a wiring board, in which peeling of a conductive layer at the periphery of an opening is capable of being sufficiently suppressed even when forming the opening for forming a via with a carbon dioxide laser, and the layered plate is also useful for manufacturing the wiring board with excellent reliability at a sufficiently high yield ratio.

### REFERENCE SIGNS LIST

1: first conductive layer, 1a: remaining portion, 1F: surface, 2: second conductive layer, 2a: remaining portion, 3, 13: insulation material layer, 3F: surface, 7: support substrate, 7a: copper layer, 7b: substrate main body, 7F: surface, 9a, 9b: conductive material, 11: resist pattern, 15: wiring layer, 20: layered plate, 21: conductive layer, H1: first opening, H1a: bottom surface, H1b: side surface, H2: second opening, H3: opening, G: groove.

1. A method for manufacturing a wiring board, the method comprising steps of:
(I) forming an insulation material layer on a surface of a support substrate;
(II) forming a first conductive layer on a surface of the insulation material layer by electroless copper plating;
(III) forming a first opening passing through the first conductive layer and the insulation material layer;
(IV) forming a second conductive layer on a surface of the first conductive layer and on a bottom surface and a side surface of the first opening by electroless copper plating;
(V) forming a resist pattern having a second opening communicating with the first opening on a surface of the second conductive layer; and
(VI) filling the first opening and the second opening with a conductive material including copper by electrolytic copper plating.

2. The method according to claim 1, wherein a thickness of the first conductive layer is 20 to 590 nm.

3. The method according to claim 1, wherein a thickness of the first conductive layer is 210 to 590 nm.

4. The method according to claim 1, wherein in the step (III), the first opening is formed with a carbon dioxide laser.

5. The method according to claim 1,
wherein the resist pattern in the step (V) further has a plurality of grooves which extend to the surface of the second conductive layer and are provided in parallel, and
in the step (VI), the plurality of grooves are also filled with a conductive material including copper by electrolytic copper plating to form a wiring.

6. The method according to claim 5, wherein a width of each of the grooves is 1 to 100 μm, and an interval between two adjacent grooves is 1 to 100 μm.

7. The method according to claim 1, further comprising steps of:
(VII) peeling the resist pattern; and
(VIII) removing the second conductive layer exposed due to peeling of the resist pattern, and the first conductive layer that is in contact with the exposed second conductive layer.

8. The method according to claim 7, wherein a multi-layered wiring layer is formed on the support substrate through steps of:
(IX) further forming an insulation material layer to cover a wiring provided on the insulation material layer after the step (VIII), and
(X) performing a series of steps from the step (II) to the step (IX) after the step (IX).

9. A layered plate, comprising:
a support substrate;
an insulation material layer provided on a surface of the support substrate; and
a conductive layer provided on a surface of the insulation material layer in a thickness of 20 to 590 nm.

10. The layered plate according to claim 9, wherein the thickness of the conductive layer is 210 to 590 nm.

11. The layered plate according to claim 9, wherein the support substrate comprises a prepreg including cloth; and a copper layer formed on a surface of the prepreg.

12. The layered plate according to claim 9, wherein the insulation material layer is a prepreg including cloth.
